(19) United States
(12) Patent Application Publication
(10) Pub. No.: US 2025/0223493 A1
(43) Pub. Date: Jul. 10, 2025

(54) COMPOSITE MATERIAL AND PREPARATION METHOD THEREOF, AND QUANTUM DOT LIGHT-EMITTING DEVICE

(71) Applicants: Guangdong Juhua Research Institute of Advanced Display, Guangzhou (CN); TCL Technology Group Corporation, Huizhou (CN)

(72) Inventors: Likuan ZHOU, Guangzhou (CN); Haikun LIU, Guangzhou (CN); Jiaqing ZHUANG, Guangzhou (CN)

(73) Assignees: Guangdong Juhua Research Institute of Advanced Display, Guangzhou (CN); TCL Technology Group Corporation, Huizhou (CN)

(21) Appl. No.: 19/005,600

(22) Filed: Dec. 30, 2024

(30) Foreign Application Priority Data
Jan. 5, 2024 (CN) 202410022131.3

(51) Int. Cl. C09K 11/88; B82Y 20/00; B82Y 40/00; C09K 11/08; C09K 11/70; H10K 50/115

(52) U.S. Cl. CPC C09K 11/883; C09K 11/0883; C09K 11/703; B82Y 20/00; B82Y 40/00; H10K 50/115

(57) ABSTRACT

The present disclosure provides a quantum dot and preparation method thereof, and a quantum dot light-emitting device. The composite material includes a first quantum dot and a second quantum dot, the surface of the first quantum dot is connected with an anionic group, and the surface of the second quantum dot is connected with a cationic group. The composite material might improve the luminescence performance of the quantum dot light-emitting device.

This application claims priority to Chinese Application No. 202410022131.3, entitled “COMPOSITE MATERIAL AND PREPARATION METHOD THEREOF, AND QUANTUM DOT LIGHT-EMITTING DEVICE”, filed on Jan. 5, 2024. The entire disclosures of the above application are incorporated herein by reference.

### TECHNICAL FIELD

The present disclosure relates to a field of display technologies, and more particularly, to a composite material and a preparation method thereof, and a quantum dot light-emitting device.

### BACKGROUND

Nowadays, organic light-emitting devices (OLEDs) and quantum dot light-emitting devices (QLEDs) are widely used light-emitting devices. QLED has become a strong competitor of OLED in recent years because of the advantages of saturated color of emitted light, adjustable wavelength, low lighting voltage, good solution processability, easy fine control of quantum dots, and high photoluminescence and electroluminescence quantum yield, etc.

Structure of conventional QLED device generally includes an anode, a hole injection layer, a hole transport layer, a light-emitting layer, an electron transport layer, an electron injection layer, and a cathode. Under the action of the electric field, the holes generated by the anode and the electrons generated by the cathode of the light-emitting device move and inject into the hole transport layer and the electron transport layer respectively, and finally migrate to the light-emitting layer. When the holes and the electrons meet in the light-emitting layer, energy excitons are generated, thereby exciting the light-emitting molecules to finally produce visible light.

In the conventional QLED, organic ligands are usually connected to the surface of the quantum dot forming the light-emitting layer, and the organic ligands are insulating, thereby the potential barrier between the quantum dots is high, which limits the transmission of carriers inside the light-emitting layer, and thus leads to poor light-emitting performance of the QLED.

### Technical Solution

In view of this, the present disclosure provides a composite material and a preparation method thereof, and a quantum dot light-emitting device, and aims to improve the problem of poor stability of light-emitting performance of the existing quantum dot light-emitting device.

First aspect, embodiments of the present disclosure provides a composite material including a first quantum dot and a second quantum dot, the surface of the first quantum dot is connected with an anionic group, and the surface of the second quantum dot is connected with a cationic group.

Alternatively, in some embodiments of the present disclosure, an element forming the anion group includes one of S, Se, Te, and P; and an element forming the cationic group includes one of Cd, Zn, Pb, Hg, and In.

Alternatively, in some embodiments of the present disclosure, a material of the second quantum dot includes at least one metal element, and the element forming the cationic group is selected from the metal element in the material of the second quantum dot.

Alternatively, in some embodiments of the present disclosure, a number of charges of the anionic group is the same as a number of charges of the cationic group.

Alternatively, in some embodiments of the present disclosure, a ratio of a number of charges of the anionic group to a number of charges of the cationic group is (0.8-0.2):1.

Alternatively, in some embodiments of the present disclosure, both the first quantum dot and the second quantum dot are core-shell quantum dot, the anionic group is connected to the outer surface of the shell of the first quantum dot, and the cationic group is connected to the outer surface of the shell of the second quantum dot.

Alternatively, in some embodiments of the present disclosure, the composite material includes a first type quantum dot having a first core-shell structure, a second type quantum dot having a second core-shell structure, and a third type quantum dot having a third core-shell structure; wherein, the first core-shell structure is configured as a non-hole confined structure, the second core-shell structure is configured as a non-electron confined structure, and the third core-shell structure is configured as a type I electron-confined and hole-confined core-shell structure.

Alternatively, in some embodiments of the present disclosure, both the first quantum dot and the second quantum dot are configured as the first type quantum dot having the first core-shell structure, thereby the composite material is configured to facilitate hole injection.

Alternatively, in some embodiments of the present disclosure, one of the first quantum dot and the second quantum dot is configured as the first type quantum dot having the first core-shell structure, and another of the first quantum dot and the second quantum dot is configured as the third type quantum dot having the third core-shell structure, thereby the composite material is configured to facilitate hole injection.

Alternatively, in some embodiments of the present disclosure, both the first quantum dot and the second quantum dot are configured as the second type quantum dot having the second core-shell structure, thereby the composite material is configured to facilitate electron injection.

Alternatively, in some embodiments of the present disclosure, one of the first quantum dot and the second quantum dot is configured as the second type quantum dot having the second core-shell structure, and another of the first quantum dot and the second quantum dot is configured as the third type quantum dot having the third core-shell structure, thereby the composite material is configured to facilitate electron injection.

Alternatively, in some embodiments of the present disclosure, both the first quantum dot and the second quantum dot are configured as the third type quantum dot having the third core-shell structure, thereby the composite material is configured to facilitate balanced transport of hole and electron.

Alternatively, in some embodiments of the present disclosure, one of the first quantum dot and the second quantum dot includes the first type quantum dot having the first core-shell structure, and another of the first quantum dot and the second quantum dot is configured as the second type quantum dot having the second core-shell structure, thereby the quantum dot is configured to facilitate balanced transport of hole and electron.

Alternatively, in some embodiments of the present disclosure, the first quantum dot includes the first type quantum dot having the first core-shell structure, the second type quantum dot having the second core-shell structure, and the third type quantum dot having the third core-shell structure; the second quantum dot includes the first type quantum dot having the first core-shell structure, the second type quantum dot having the second core-shell structure, and the third type quantum dot having the third core-shell structure; thereby the composite material is configured to facilitate balanced transport of hole and electron.

Alternatively, in some embodiments of the present disclosure, an average particle diameter of the first quantum dot is 5 nm-25 nm, and an average particle diameter of the second quantum dot is 5 nm-25 nm.

Alternatively, in some embodiments of the present disclosure, the first quantum dot and the second quantum dot each independently includes one or more of a single structure quantum dot, a core-shell quantum dot, and a perovskite-type semiconductor material; a material of the single structure quantum dot, a core material of the core-shell quantum dot, and a shell material of the core-shell quantum dot may include one or more of a Group II-VI compound, a Group IV-VI compound, a Group III-V compound, and a Group I-III-VI compound, respectively, the Group II-VI compound includes one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the Group IV-VI compound includes one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe; the Group III-V compound includes one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the Group I-III-VI compound includes one or more of CuInS₂, CuInSe₂, and AgInS₂; the perovskite-type semiconductor material includes a doped or undoped inorganic perovskite-type semiconductor or an organic-inorganic hybrid perovskite-type semiconductor, the inorganic perovskite-type semiconductor has a structural general formula AMX₃, where A is a Cs⁺ ion; M is a divalent metal cation including one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺; X is a halogen anion including one or more of Cl⁻, Br⁻, and I⁻; the organic-inorganic hybrid perovskite-type semiconductor includes CH₃(CH₂)ₙ₋₂NH₃⁺ or [NH₃(CH₂)ₙNH₃]²⁺, where n≥2; M is a divalent metal cation including one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺; and X is a halogen anion including one or more of Cl⁻, Br⁻, and I⁻.

Second aspect, embodiments of the present disclosure further provides a method of preparing a composite material, the method includes:
providing a third quantum dot solution including third quantum dots, the third quantum dot solution includes a first organic solvent and third quantum dots dispersed in the first organic solvent, and first ligands are connected to the surface of each of the third quantum dots;
providing an anionic ligand solution including anionic groups, and the anionic ligand solution includes a second organic solvent and anionic ligands dispersed in the second organic solvent;
mixing the third quantum dot solution with the anionic ligand solution, and exchanging the first ligands with the anionic groups to obtain first quantum dot, and the surface of each of the first quantum dots is connected with the anionic groups;
separating the first quantum dots, and dispersing the first quantum dots in the second organic solvent to obtain a first quantum dot solution;
providing a cationic ligand solution including cationic groups, and the cationic ligand solution includes a third organic solvent and cationic ligands dispersed in the third organic solvent;
mixing the first quantum dot solution with the cationic ligand solution, and exchanging the anionic groups with the cationic groups to obtain second quantum dots, and the surface of each of the second quantum dots is connected with the cationic groups;
dispersing the second quantum dots in the second organic solvent to obtain a second quantum dot solution;
mixing the first quantum dot solution with the second quantum dot solution to obtain the composite material.

Alternatively, in some embodiments of the present disclosure, the anionic ligands include Na₂S or (NH₄)₂S.

Alternatively, in some embodiments of the present disclosure, the cationic ligands include a soluble metal salt, and the soluble metal include one of Cd, Zn, Pb, Hg, and In.

Alternatively, in some embodiments of the present disclosure, the first organic solvent is an C6-C18 alkane.

Alternatively, in some embodiments of the present disclosure, the second organic solvent includes NMF, DMSO, MEK, ACN, or a thiol organic solvent.

Alternatively, in some embodiments of the present disclosure, the second organic solvent includes NMF, DMSO, MEK, or CAN.

Alternatively, in some embodiments of the present disclosure, the first ligands include decanoic acid, undecylenic acid, myristanoic acid, oleic acid, linoleic acid, stearic acid, octanethiol, dodecylmercaptan, octadecylmercaptan, oleylamine, octadecylamine, octylamine, dioctylamine, trioctylamine, tri-n-octylphosphine, tri-n-octylphosphine oxide.

Third aspect, embodiments of the present disclosure further provides another method of preparing a composite material, and the method includes:
providing a third quantum dot solution including third quantum dots, the third quantum dot solution includes a first organic solvent and third quantum dots dispersed in the first organic solvent, and first ligands are connected to the surface of each of the third quantum dots;
providing a fourth quantum dot solution including fourth quantum dots, wherein the fourth quantum dot solution includes a first organic solvent and fourth quantum dots dispersed in the first organic solvent, and second ligands are connected to the surface of each of the fourth quantum dots;
providing an anionic ligand solution including anionic groups, and the anionic ligand solution includes a second organic solvent and anionic ligands dispersed in the second organic solvent;
mixing the third quantum dot solution with the anionic ligand solution, and exchanging the first ligands with the anionic groups to obtain first quantum dots, and the surface of each of the first quantum dots is connected with the anionic groups; and dispersing the first quantum dots in the second organic solvent to obtain a first quantum dot solution;
mixing the fourth quantum dot solution with the anionic ligand solution, and exchanging the second ligands with the anionic groups to obtain fifth quantum dots, and the surface of each of the fifth quantum dots is connected with the anionic groups; and dispersing the fifth quantum dots in the second organic solvent to obtain a fifth quantum dot solution;
providing a cationic ligand solution including cationic groups, and the cationic ligand solution includes a third organic solvent and cationic ligands dispersed in the third organic solvent;
mixing the fifth quantum dot solution with the cationic ligand solution, and exchanging the anionic groups with the cationic groups to obtain second quantum dots, and the surface of each of the second quantum dots is connected with the cationic groups; and dispersing the second quantum dots in the second organic solvent to obtain a second quantum dot solution;
mixing the first quantum dot solution with the second quantum dot solution to obtain the composite material.

Alternatively, in some embodiments of the present disclosure, the anionic ligands include Na₂S or (NH₄)₂S.

Alternatively, in some embodiments of the present disclosure, the cationic ligands include a soluble metal salt, and the soluble metal include one of Cd, Zn, Pb, Hg, and In.

Alternatively, in some embodiments of the present disclosure, the first organic solvent is an C6-C18 alkane.

Alternatively, in some embodiments of the present disclosure, the second organic solvent includes NMF, DMSO, MEK, ACN, or a thiol organic solvent.

Alternatively, in some embodiments of the present disclosure, the second organic solvent includes NMF, DMSO, MEK, or CAN.

Alternatively, in some embodiments of the present disclosure, the first ligands include decanoic acid, undecylenic acid, myristanoic acid, oleic acid, linoleic acid, stearic acid, octanethiol, dodecylmercaptan, octadecylmercaptan, oleylamine, octadecylamine, octylamine, dioctylamine, trioctylamine, tri-n-octylphosphine, tri-n-octylphosphine oxide. Alternatively, in some embodiments of the present disclosure, the second ligands include decanoic acid, undecylenic acid, myristanoic acid, oleic acid, linoleic acid, stearic acid, octanethiol, dodecylmercaptan, octadecylmercaptan, oleylamine, octadecylamine, octylamine, dioctylamine, trioctylamine, tri-n-octylphosphine, tri-n-octylphosphine oxide.

Fourth aspect, embodiments of the present disclosure further provides a quantum dot light-emitting device comprising an anode, a cathode, and a light-emitting layer disposed between the anode and the cathode. A material forming the light-emitting layer comprises the composite material describe above.

The composite material provided in the present disclosure includes a first quantum dot and a second quantum dot, the first quantum dot has an anionic group, and the second quantum dot has a cationic group. The composite material might improve the luminescence performance of the quantum dot light-emitting device.

### BRIEF DESCRIPTION OF DRAWINGS

In order to more clearly explain the technical solutions in the embodiments of the present disclosure, the drawings to be used in the description of the embodiments are briefly described below. It is apparent that the drawings in the following description are merely some embodiments of the present disclosure. For those skilled in the art, without involving any creative effort, other drawings may be obtained based on these drawings. In the following description, the same reference numerals denote the same parts.

FIG. 1 is a schematic structural diagram of a quantum dot light-emitting device according to an embodiment of the present disclosure;

FIG. 2 is a schematic structural diagram of a quantum dot light-emitting device according to another embodiment of the present disclosure;

FIG. 3 is a schematic diagram of a process of anionic ligand exchange of a quantum dot according to an embodiment of the present disclosure;

FIG. 4 is a schematic diagram of an assembly process of a quantum dot fusion unit according to an embodiment of the present disclosure;

FIG. 5 is a flowchart of a method of preparing a composite material according to an embodiment of the present disclosure;

FIG. 6 is a flowchart of another method of preparing a composite material according to an embodiment of the present disclosure.

### DETAILED DESCRIPTION

Technical solutions in embodiments of the present disclosure will be clearly and completely described below with reference to the drawings in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure.

Unless otherwise defined, all technical and scientific terms used herein have the same meaning as commonly understood by those skilled in the art belonging to the present disclosure. The terminology used herein in the specification of the present disclosure is for the purpose of describing specific embodiments only, and is not intended to limit the present disclosure. The term “and/or” as used herein includes any and all combinations of one or more associated listed items.

In the present disclosure, unless stated to the contrary, the location words used such as “upper” and “lower” usually refer to the upper and lower in the actual use or working state of the device, specifically the drawing direction in the drawings. While “inner” and “outer” are for the outline of the device. In addition, in the description of the present disclosure, the term “comprising” means “including but not limited to”. The terms first, second, third, etc. are used for indication only, and do not impose numerical requirements or establish order.

In the present disclosure, “and/or” describes the association relationship of the association object, and indicates that there may be three kinds of relationships, for example, A and/or B, which may indicate that A exists alone, A and B exist at the same time, and B exists alone, where A, B may be singular or plural.

In the present disclosure, the term “at least one” refers to one or more, and “a plurality of/multiple” refers to two or more. The terms “one or more”, “at least one of the followings”, and the like, refer to any combination of the items listed, and including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural (multiple).

In the present disclosure, when another layer is formed “on” a certain layer, the so-called “upper” is a broad concept, and may mean that the other layer is formed adjacent to the certain layer, or may mean that another spacer structure layer exists between the other layer and the certain layer, for example, a second electrode is formed “on” the first carrier functional layer, and the so-called “upper” may mean that the second electrode is formed adjacent to the first carrier functional layer, or may mean that another spacer structure layer exists between the second electrode and the first carrier functional layer, for example, a light-emitting layer.

Various embodiments of the present disclosure may be presented in a form of range. It should be understood that the description in the form of range is merely for convenience and brevity, and should not be construed as a hard limitation on the scope of the disclosure. Therefore, it should be considered that the recited range description has specifically disclosed all possible subranges, as well as a single numerical value within that range. For example, it should be considered that a description of a range from 1 to 6, more specifically, a range such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range

First aspect, referring to FIG. 1, an embodiment of the present disclosure provides a quantum dot light-emitting device 100 including an anode 10, a light-emitting layer 20, and a cathode 30 stacked in order. The light-emitting layer 20 is disposed between the anode 10 and the cathode 30.

In an embodiment, the quantum dot light-emitting device 100 further includes a hole transport layer 40 disposed between the anode 10 and the light-emitting layer 20. In other words, the light-emitting device 100 includes an anode 10, a hole transport layer 40, a light-emitting layer 20, and a cathode 30 stacked in order.

In an embodiment, the quantum dot light-emitting device 100 further includes an electron transport layer 50 disposed between the light-emitting layer 20 and the cathode 30. In other words, the light-emitting device 100 includes an anode 10, a hole transport layer 40, a light-emitting layer 20, an electron transport layer 50, and a cathode 30 stacked in order.

In an embodiment, the quantum dot light-emitting device 100 further includes a hole injection layer 60 disposed between the anode 10 and the hole transport layer 40. In other words, the quantum dot light-emitting device 100 includes an anode 10, a hole injection layer 60, a hole transport layer 40, a light-emitting layer 20, an electron transport layer 50, and a cathode 30 stacked in order.

In an embodiment, the quantum dot light-emitting device 100 further includes a substrate 70. The substrate 70 may be a rigid substrate or a flexible substrate, and a specific material used for forming the substrate 70 may include at least one of glass, silicon wafer, polycarbonate, poly(methyl methacrylate), polyethylene terephthalate, polyethylene naphthalate (PEN), polyamide, and polyethersulfone.

The quantum dot light-emitting device 100 may have an upright structure or an inverted structure.

As shown in FIG. 1, a schematic structural diagram of a quantum dot light-emitting device 100 having an upright structure is provided. The quantum dot light-emitting device 100 includes a substrate 70, an anode 10 disposed on an upper surface of the substrate 70, a hole injection layer 60 disposed on an upper surface of the anode 10, a hole transport layer 40 disposed on an upper surface of the hole injection layer 60, a light-emitting layer 20 disposed on an upper surface of the hole transport layer 40, an electron transport layer 50 disposed on an upper surface of the light-emitting layer 20, and a cathode 30 disposed on an upper surface of the electron transport layer 50.

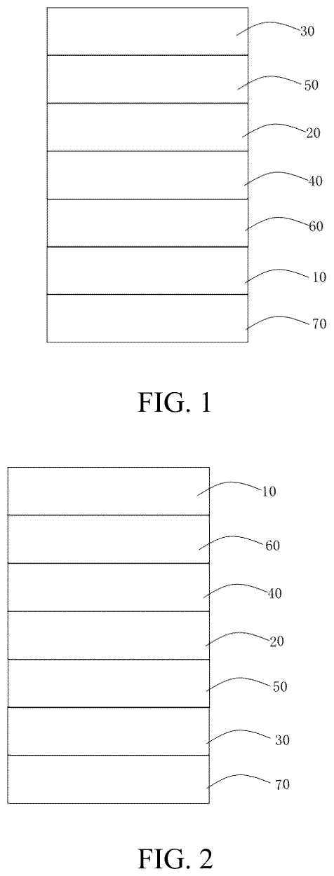

As shown in FIG. 2, a schematic structural diagram of a quantum dot light-emitting device 100 having an inverted structure is provided. The quantum dot light-emitting device 100 includes a substrate 70, a cathode 30 disposed on an upper surface of the substrate 70, an electron transport layer 50 disposed on an upper surface of the cathode 30, a light-emitting layer 20 disposed on an upper surface of the electron transport layer 50, a hole transport layer 40 disposed on an upper surface of the light-emitting layer 20, a hole injection layer 60 disposed on an upper surface of the hole injection layer 60, and an anode 10 disposed on an upper surface of the hole injection layer 60.

In some preferred embodiments, a material of the anode 10 is selected from one or more of indium tin oxide, fluorine-doped tin oxide, indium zinc oxide, graphene, carbon nanotubes. A material of the hole injection layer 60 is a conventional aqueous PEDOT:PSS solution. A material of the hole transport layer 40 is selected from one or more of PVK (polystyrene-based compound), Poly-TPD (poly-N,N′-diphenyl-N,N′-dimethylaniline), CBP (2,2′-bis(1,3-benzothiadiazolyl) biphenyl), TCTA (4,4′,4′-tris(fluorene-2,7-yl)triphenylamine) and TFB (Poly(9,9-dioctylfluorene-co-N-(4-butylphenyl)diphenylamine)). The light-emitting layer 20 includes a red quantum dot light-emitting layer, a green quantum dot light-emitting layer, or a blue quantum dot light-emitting layer. A material of the electron transport layer 50 is an n-type ZnO, or an n-type ZnO doped with one or more of Al, Mg, Ga, and Sn. A material of the cathode 30 is selected from one or more of Al, Ca, Ba, and Ag.

Quantum dot light-emitting device (QLED) may be applied in the lighting and display industries due to their unique optoelectronic characteristics. The stability and lifetime of the QLED are still key issues facing the commercial application of QLED. One of the key problems affecting the working stability and luminescence performance of the quantum dot light-emitting device is the unbalanced carrier injection in the quantum dot light-emitting device, that is, there is a multi-hole quantum dot light-emitting device or a multi-electron quantum dot light-emitting device. Too many holes in the multi-hole quantum dot light-emitting device may lead to rapid deterioration of the quantum dot light-emitting device and permanent deterioration of the quantum dot light-emitting device, and too many electrons in the multi-electron quantum dot light-emitting device may lead to a decrease in carrier injection efficiency and lead to a deterioration problem of the light-emitting device.

In related arts, in order to improve the working performance of the quantum dot light-emitting device, electron injection is reduced to achieve balanced charge in the quantum dot light-emitting device, for example, an electron blocking layer is disposed between the light-emitting layer and the electron transport layer. A material of the electron blocking layer include polymethyl methacrylate (PMMA), polyethyleneimine (PEI), alumina, and Cs₂CO₃, and the like. However, with the incorporation of the electron blocking layer in the quantum dot light-emitting device, the internal resistance of the quantum dot light-emitting device increases, which is not conducive to further improvement of the performance of the QLED.

In the study of improving the working performance of quantum dot light-emitting device, the inventors found that it is relatively difficult to control the carrier injection balance of the quantum dot light-emitting device by controlling the use of less hole-transport layer materials and electron-transport layer materials, and at the same time, it is difficult to effectively control the carrier injection balance by changing the selection of quantum dot materials completely due to the difference of energy level positions of quantum dot materials of different light-emitting layers. Therefore, adjusting the relative injection level of electrons and holes by changing the structure of the composite material forming the light-emitting layer is essential to realize the carrier balance of the quantum dot light-emitting device.

Second aspect, an embodiment of the present disclosure provides a composite material for forming the above-described light-emitting layer. In the embodiments of the present disclosure, a composite material having a core-shell structure is used to form the light-emitting layer. The composite material includes quantum dot. The quantum dot includes a core and at least one shell covering the core, and an organic ligand is further connected to the outer surface of the shell of the quantum dot. The core of the quantum dot is used to emit light, and the shell is used to form a passivation shell layer with a wide band gap, thereby enhancing the structural stability of the quantum dot. The organic ligand modifies the outer surface of the quantum dot, thus enhancing the stability and dispersion of the quantum dot.

A material of the core of the quantum dot and a material of the shell of the quantum dot may include a binary alloy, a multi-element alloy, or a multi-element graded alloy. The binary alloy, the multi-element alloy, and the multi-element graded alloy may be composed of a Group II-VI element, a Group III-V element, and a Group IV-VI element. For example, a composite material of the core-shell structure may include, but not limited to, one or more of CdSe/CdSeS/CdS, InP/ZnSeS/ZnS, CdZnSe/ZnSe/ZnS, CdSeS/ZnSeS/ZnS, CdSe/ZnS, CdSe/ZnSe/ZnS, ZnSe/ZnS, ZnSeTe/ZnS, CdSe/CdZnSeS/ZnS, and InP/ZnSe/ZnS.

In some embodiments, the material of the core of the quantum dot includes at least one of CdSe, CdS, CdTe, CdSeTe, CdZnS, PbSe, ZnTe, CdSeS, PbS, PbTe, HgS, HgSe, HgTe, GaP, GaAs, InP, InAs, InZnP, and InGaP. The material of the outer shell of the quantum dot includes one or more of CdS, CdTe, CdSeTe, CdZnSe, CdZnS, CdSeS, ZnSe, ZnSeS, ZnS, PbS, PbSeS, InZnP, and InGaP.

The organic ligand connected to the quantum dot includes at least one of a substituted or unsubstituted C6 to C24 fatty acid, a substituted or unsubstituted C6 to C24 fatty amine, a substituted or unsubstituted C6 to C24 aliphatic thiol, a substituted or unsubstituted C6 to C24 aliphatic thioether, a substituted or unsubstituted C6 to C24 aliphatic phosphine, a substituted or unsubstituted C6 to C24 aliphatic phosphine oxide, a substituted or unsubstituted C8 to C20 aliphatic phosphoric acid, a substituted or unsubstituted C6 to C24 aliphatic phosphoric acid ester, a substituted or unsubstituted C6 to C24 aliphatic phosphorous acid, and a substituted or unsubstituted C6 to C24 aliphatic phosphorous acid ester. The substituted substituent is selected from at least one of a C₁ to C₆ alkyl group, a C₁ to C₆ alkoxy group, and a halogen.

Optionally, the substituted or unsubstituted C6 to C24 fatty acid includes at least one of decanoic acid, undecylenic acid, myristanoic acid, oleic acid, linoleic acid, and stearic acid.

Optionally, the substituted or unsubstituted C6 to C24 aliphatic thiol includes at least one of octanethiol, dodecylmercaptan, and octadecylmercaptan.

Optionally, the substituted or unsubstituted C6 to C24 fatty amine includes at least one of oleylamine, octadecylamine, octylamine, dioctylamine, and trioctylamine.

Optionally, the substituted or unsubstituted C6 to C24 aliphatic phosphine includes tri-n-octylphosphine (TOP).

Optionally, the substituted or unsubstituted C6 to C24 aliphatic phosphine oxide includes tri-n-octylphosphine oxide (TOPO).

In the embodiments of the present disclosure, by optimizing the material combination structure of the quantum dots, the carrier injection balance of the quantum dot light-emitting device is adjusted, and the instability of the quantum dot light-emitting device caused by the imbalance of the carriers is improved.

In a specific implementation, a composite material forming the light-emitting layer includes a first quantum dot and a second quantum dot. The surface of the first quantum dot is connected with an anionic group, and the surface of the second quantum dot is connected with a cationic group.

Through the electrostatic interaction between the first quantum dot and the second quantum dot, the interlayer barrier between quantum dots might be reduced, which is beneficial to the transportation of carriers inside the light-emitting layer.

In some embodiments, a number of charges of the anionic group connected to the outer surface of the first quantum dot and a number of charges of the cationic group connected to the outer surface of the second quantum dot are arranged to be the same, so that the first quantum dot and the second quantum dot have an electrostatic attraction effect to perform fusion assembly, and the surface defect state of the quantum dot might be repaired through the fusion assembly process, which is beneficial to improve the carrier injection balance.

Alternatively, a ratio of the number of charges of the anionic group to the number of charges of the cationic group is (0.8-0.2):1. In some specific examples, the ratio of the number of charges of the anionic group to the number of charges of the cationic group may be 0.8:1, 0.9:1, 1.0:1, 1.1:1, 1.2:1, and a value between any two of the above values or a range between any two of the above values.

Compared with the related art, organic ligands are connected to the outer surface of the core-shell quantum dot. The organic ligands are usually insulated to make the light-emitting layer closer to the insulating layer, which is not conducive to the transportation of carriers in the light-emitting layer. By connecting the anionic group or the cationic group on the outer surface of the core-shell quantum dot, the quantum dots with charge groups is conducive to reducing the interlayer barrier between various layer levels of the quantum dot. The first quantum dot connected with the anionic group has a stronger hole attraction force due to the higher negative charge density on its surface, and the second quantum dot connected with the cationic group has a stronger electron attraction force due to the higher positive charge density on its surface, thereby there is stronger electronic attraction between the first quantum dot and the second quantum dot, thus promoting carrier transport in the light-emitting layer, which is beneficial to improving the light-emitting performance of the quantum dot light-emitting device.

In some embodiments, in view of the need for functionalization of the anionic group connected to the outer surface of the first quantum dot, for example, the anionic group needs to have as little steric hindrance as possible, the anionic group suitably connected to the surface of the first quantum dot is configured as an anion composed of a single chemical element. The chemical element forming the anion is preferably derived from a non-metallic element of Group V or a non-metallic element of Group VI, and suitable elements include S, Se, Te, P, and the like.

In a further preferred embodiment, considering the preparation process of the composite, the chemical element suitable for forming the anionic group is S.

In some embodiments, the cationic group suitably connected to the surface of the second quantum dot is configured as a cation composed of a single chemical element. The chemical element forming the cation includes a metal element or a transition metal element, and suitable elements include Cd, Zn, Pb, Hg, In, and the like.

In a further preferred embodiment, considering the preparation process of the composite material, the chemical element suitable for forming the cationic group remain the same as one of the chemical elements in bulk material of the quantum dots.

In some embodiments, the chemical formula of the first quantum dot is QD/S²⁻, that is, S²⁻ is connected to the outer surface of the first quantum dot. The chemical formula of the second quantum dot is QD/M²⁺. Two negative charges are connected to the outer surface of the first quantum dot, and two positive charges are connected to the outer surface of the second quantum dot. On the one hand, it is beneficial for the charged group to form a smaller steric hindrance on the outer surface of the quantum dot, thereby being beneficial for connecting a plurality of anionic groups on the outer surface of the first quantum dot or a plurality of cationic groups on the outer surface of the second quantum dot. On another hand, a plurality of anionic groups of the first quantum dot and a plurality of cationic groups of the second quantum dot are fused and assembled, it is beneficial for defect repair of a plurality of outer surfaces of the first quantum dot connected with the anionic groups, and it is beneficial for defect repair of a plurality of outer surfaces of the second quantum dot connected with the cationic groups, thereby the carrier injection efficiency is improved.

The core-shell quantum dot is a type of nano-material. The core-shell quantum dot includes a core and at least one shell covering the core, a material of the core is usually a metal or semiconductor material, and this structure makes the quantum dot have special optoelectronic properties.

In the embodiments of the present disclosure, the band gap (Eg) of the quantum dot of the core-shell quantum dot is preferably 1.9 eV-2.75 eV. The quantum dot light-emitting device correspondingly generates red light when the band gap Eg of the quantum dot is 1.9 eV-2.2 eV, the quantum dot light-emitting device correspondingly generates green light when the band gap Eg of the quantum dot is 2.25 eV-2.38 eV, and the quantum dot light-emitting device correspondingly generates blue light when the band gap Eg of the quantum dot is 2.58 eV-2.75 eV.

In the core-shell quantum dot, conduction band energy level difference and valence band energy level difference are two important parameters to describe the electronic energy level distribution of the core-shell quantum dot, which are of great significance to the photoelectric performance of the core-shell quantum dot.

In the embodiments of the present disclosure, the bottom energy level of the conduction band of the material of the core is referred to as E_{CB, core}, and the bottom energy level of the conduction band of the material of the shell is referred to as E_{CB, shell}, and the conduction band energy level difference between the material of the shell and the material of the core is expressed as ΔE_{CB, shell-core}=E_{CB, shell}−E_{CB, core}. The magnitude of the conduction band energy level difference represents the ability of electron transport between the core and the shell, when the conduction band energy level difference is large, electrons are more easily transported from the core to the shell, which enhances the conductivity and photoelectric conversion efficiency of the core-shell quantum dot.

In the embodiments of the present disclosure, the top energy level of the valence band of the material of the core is referred to as E_{VB, core}, the top energy level of the valence band of the material of the shell is referred to as E_{VB, shell}, and the valence band energy level difference between the material of the shell and the material of the core is expressed as ΔE_{VB, shell-core}=E_{VB, shell}−E_{VB, core}. The magnitude of the valence band energy level difference represents the energy difference of electrons between the material of the core and the material of the shell, when the valence band energy level difference is large, the energy difference of the electrons transition from the core to shell is large.

The magnitude of the conduction band energy level difference is related to factors such as the energy band junction between the material of the core and the material of the shell, the energy level of the material, the lattice matching, and the like. In the embodiments of the present disclosure, the magnitude of the conduction band energy level difference between the material of the core and the material of the shell is finely adjusted to realize the fine adjustment of the electronic properties of the core-shell quantum dot.

The magnitude of the valence band energy level difference is related to factors such as the combination of the material of the core and the material of the shell, the thickness of the shell, the crystallinity, and the like. In the embodiments of the present disclosure, the value of the valence band energy level difference of the quantum dot is finely regulated, thereby the energy band structure and optical properties of the quantum dot are further regulated.

The conduction band energy level difference of the above core-shell quantum dot and valence band energy level difference of the above core-shell quantum dot might be obtained by experimental measurement techniques or theoretical algorithms.

In some embodiments of the present disclosure, according to the differences in the relative position and arrangement of energy bands between the material of the core and the material of the shell of the quantum dot having a core-shell structure, the quantum dot includes a first type quantum dot having a first core-shell structure, a second type quantum dot having a second core-shell structure, and a third type quantum dot having a third core-shell structure.

Moreover, in the first type quantum dot, the first core-shell structure is configured as a non-hole confined structure. The valence band energy level difference between the material of the shell and the material of the core of the quantum dot ΔE_{VB, shell-core}≥−0.2 eV, and the conduction band energy level difference between the material of the shell and the material of the core of the quantum dot ΔE_{CB, shell-core}≥0.2 eV. The value of the valence band energy level difference between the core and the shell of the quantum dot is large, thereby holes might be delocalized in the core and shell range of the quantum dot, and the hole wave function between the quantum dots generates more overlapping areas in the quantum dot film formed by the quantum dot, it is beneficial to the transmission of the holes between the quantum dots. More first type quantum dot adopted in the quantum dot light-emitting device is beneficial to improve the hole injection level of the quantum dot light-emitting device.

In the second type quantum dot, the second core-shell structure is configured as a non-electron confined structure. The valence band energy level difference between the material of the shell and the material of the core of the quantum dot ΔE_{VB, shell-core}≤−0.2 eV, and the conduction band energy level difference between the material of the shell and the material of the core of the quantum dot ΔE_{CB, shell-core}≤0.2 eV. The value of the valence band energy level difference between the core and the shell of the quantum dot is small, thereby electrons might be delocalized in the core and shell range of the quantum dot, and the electron wave function between the quantum dots generates more overlapping areas in the quantum dot film formed by the quantum dot, it is beneficial to the transmission of the electrons between the quantum dots. More second type quantum dot adopted in the quantum dot light-emitting device is beneficial to improve the electron injection level of the quantum dot light-emitting device.

In the third type quantum dot, the third core-shell structure is configured as a type I electron-confined and hole-confined core-shell structure. The valence band energy level difference between the shell material and the core material of the quantum dot ΔE_{VB, shell-core}≤−0.2 eV, and the conduction band energy level difference between the shell material and the core material of the quantum dot ΔE_{CB, shell-core}≥0.2 eV. Both the electrons and the holes inside the quantum dot are confined inside the inner core. Because of the difference of carrier injection barrier between the quantum dot and the adjacent electron transport layer or between the quantum dot and the adjacent hole transport layer, there is asymmetry of the transport barrier between the electrons and holes.

Moreover, the first type quantum dot, the second type quantum dot and the third type quantum dot are mainly based on the valence band energy level difference and the conduction band energy level difference between the material of the shell and the material of the core, then a suitable binary alloy or a suitable multi-element alloy is selected, and the band gap and energy level position of the quantum dot are adjusted by adjusting the component content of each metal element of the binary alloy or the multi-element alloy, so that the first type quantum dot has non-hole-confined core-shell structure characteristic, the second type quantum dot has non-electron-confined core-shell structure characteristic, and the third type quantum dot has I-type electron-confined and hole-confined core-shell structure characteristic.

In the embodiments of the present disclosure, composite material combination structures with different core-shell structures are provided for quantum dot light-emitting devices of different systems, thereby effectively promoting carrier injection balance and improving working stability of the quantum dot light-emitting devices.

In an embodiment, in a multi-electron system quantum dot light-emitting device, the composite material forming the light-emitting layer adopts first type quantum dots having the non-hole-confined core-shell structure The surfaces of a part of first type quantum dots are connected with anionic groups, and the surfaces of another part of the first type quantum dots are connected with cationic groups, and the first type quantum dots with anionic groups and the first type quantum dots with cationic groups are fused and assembled to form a light-emitting layer.

In another alternative embodiment, in a multi-electron system quantum dot light-emitting device, the composite material forming the light-emitting layer adopts first type quantum dots having the non-hole-confined core-shell structure and third type quantum dots having the type I electron-confined and hole-confined core-shell structure. Surfaces of a part of the first type quantum dots are connected with anionic groups, surfaces of another part of the first type quantum dots are connected with cationic groups, surfaces of a part of the third type quantum dots are connected with anionic groups, and surfaces of another part of the third type quantum dots are connected with cationic groups. The first type quantum dots with anionic groups and the third type quantum dots with cationic groups are fused and assembled to form a light-emitting layer, or the third type quantum dots with anionic groups and the first type quantum dots with cationic groups are fused and assembled to form a light-emitting layer.

In an embodiment, in a multi-hole system quantum dot light-emitting device, the composite material forming the light-emitting layer adopts second type quantum dots having the non-electron-confined core-shell structure, wherein the surfaces of a part of the second type quantum dots are connected with anionic groups, and the surfaces of another part of the second type quantum dots are connected with cationic groups, and the second type quantum dots with anionic groups and the second type quantum dots with cationic groups are fused and assembled to form a light-emitting layer.

In another alternative embodiment, in a multi-hole system quantum dot light-emitting device, the composite material forming the light-emitting layer adopts second type quantum dots having the non-electron-confined core-shell structure and third type quantum dots having the type I electron-confined and hole-confined core-shell structure. Surfaces of a part of the second type quantum dots are connected with anionic groups, surfaces of another part of the second type quantum dots are connected with cationic groups, surfaces of a part of the third type quantum dots are connected with anionic groups, and surfaces of another part of the third type quantum dots are connected with cationic groups. The second type quantum dots with anionic groups and the third type quantum dots with cationic groups are fused and assembled to form a light-emitting layer, or the third type quantum dots with anionic groups and the second type quantum dots with cationic groups are fused and assembled to form a light-emitting layer.

In an embodiment, in a quantum dot light-emitting device with relatively hole-electron balance, the composite material forming the light-emitting layer adopts first type quantum dots having the non-hole-confined core-shell structure and second type quantum dots having the non-electron-confined core-shell structure. Surfaces of a part of the first type quantum dots are connected with anionic groups, surfaces of another part of the first type quantum dots are connected with cationic groups, surfaces of a part of the second type quantum dots are connected with anionic groups, and surfaces of another part of the second type quantum dots are connected with cationic groups. The first type quantum dots with anionic groups and the second type quantum dots with cationic groups are fused and assembled to form a light-emitting layer, or the second type quantum dots with anionic groups and the first type quantum dots with cationic groups are fused and assembled to form a light-emitting layer.

In another alternative embodiment, in a quantum dot light-emitting device with relatively hole-electron balance, the composite material forming the light-emitting layer adopts third type quantum dots having the type I electron-confined and hole-confined core-shell structure. The surfaces of a part of the third type quantum dots are connected with anionic groups, and the surfaces of another part of the third type quantum dots are connected with cationic groups, and the third type quantum dots with anionic groups and the third type quantum dots with cationic groups are fused and assembled to form a light-emitting layer.

In another alternative embodiment, in a quantum dot light-emitting device with relatively hole-electron balance, the composite material forming the light-emitting layer adopts first type quantum dots having the non-hole-confined core-shell structure, second type quantum dots having the non-electron-confined core-shell structure, and third type quantum dots having the type I electron-confined and hole-confined core-shell structure. Surfaces of the first type quantum dots, surfaces of the second type quantum dots, and surfaces of the third type quantum dots are connected with anionic groups or cationic groups. At least one of the first quantum dots, the second quantum dots, and the third quantum dots have anionic groups connected to the surfaces, and at least one of the first quantum dots, the second quantum dots, and the third quantum dots have cationic groups connected to the surfaces. The quantum dots with anionic groups and the quantum dots with cationic groups are fused and assembled to form a light-emitting layer.

In some embodiments, an average particle diameter of the first quantum dot is 5 nm-25 nm, and/or an average particle diameter of the second quantum dot is 5 nm-25 nm. For example, the average particle diameter of the first quantum dot or the second quantum dot may be 7 nm, 9 nm, 11 nm, 13 nm, 15 nm, 17 nm, 19 nm, 21 nm, 23 nm, and a numerical diameter between any two of the above numerical values or a range between any two of the above numerical values.

In some embodiments, the first quantum dot and the second quantum dot each independently includes one or more of a single structure quantum dot, a core-shell quantum dot, and a perovskite-type semiconductor material.

Moreover, a material of the single structure quantum dot, a core material of the core-shell quantum dot, and a shell material of the core-shell quantum dot may include one or more of a Group II-VI compound, a Group IV-VI compound, a Group III-V compound, and a Group I-III-VI compound, respectively.

The Group II-VI compound includes one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe. The Group IV-VI compound includes one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe. The Group III-V compound includes one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb. The Group I-III-VI compound includes one or more of CuInS₂, CuInSe₂, and AgInS₂.

The perovskite-type semiconductor material includes a doped or undoped inorganic perovskite-type semiconductor or an organic-inorganic hybrid perovskite-type semiconductor. The inorganic perovskite-type semiconductor has a structural general formula AMX₃, where A is a Cs⁺ ion; M is a divalent metal cation including one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺; X is a halogen anion including one or more of Cl⁻, Br⁻, and I⁻. The organic-inorganic hybrid perovskite-type semiconductor includes CH₃(CH₂)ₙ₋₂NH₃⁺ or [NH₃(CH₂)ₙNH₃]²⁺, where n≥2; M is a divalent metal cation including one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺; and X is a halogen anion including one or more of Cl⁻, Br⁻, and I⁻.

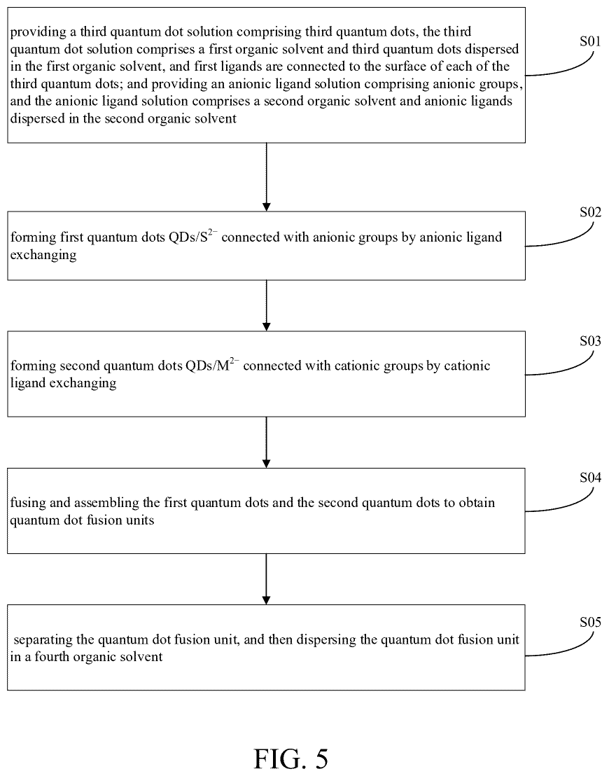

Third aspect, referring to FIG. 5, embodiments of the present disclosure provide a method of preparing the above-described composite material, the method includes:

Step S01: providing a third quantum dot solution including third quantum dots, wherein the third quantum dot solution includes a first organic solvent and third quantum dots dispersed in the first organic solvent, and first ligands are connected to the surface of each of the third quantum dots;

Providing an anionic ligand solution including anionic groups, wherein the anionic ligand solution includes a second organic solvent and anionic ligands dispersed in the second organic solvent.

The first ligands used in the Step S01 include a conventional organic ligand, and a composite material connected with the conventional organic ligand is prepared by using a related technology. Moreover, a synthesis method for synthesizing the composite material connected with the conventional organic ligand includes a process such as a one-pot method or a two-step method in the related technology, a binary alloy or a multi-element alloy of the core of the quantum dot is synthesized according to specific requirements, and at least one shell of the quantum dot is generated by an alternating ion layer adsorption generation method.

The anionic ligands employed in the Step S01 include Na₂S or (NH₄)₂S. The first organic solvent is an a C6-C18 alkane reagent, and suitable alkane reagent includes one of N-hexane reagent, and N-octane reagent. The second organic solvent includes NMF (N-methylformamide) solution, DMSO (dimethyl sulfoxide) solvent, MEK (methyl ethyl ketone) solvent, ACN (acetonitrile) solvent, or a thiol organic solvent, wherein a suitable thiol organic solvent includes methanethiol.

Step S02: forming first quantum dots QDs/S²⁻ connected with anionic groups by anionic ligand exchanging, and the specific steps include:
Mixing the third quantum dot solution with the anionic ligand solution, and exchanging the first ligands with the anionic groups to obtain first quantum dots, and the surface of each of the first quantum dots is connected with the anionic groups;
Separating the first quantum dots, and dispersing the first quantum dots in the second organic solvent to obtain a first quantum dot solution.

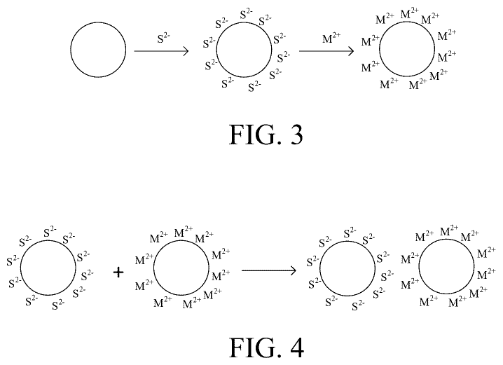

The process diagram of the anionic ligand exchanging referring to FIG. 3. In order to promote the first quantum dot to enter the second organic solvent, the immiscible first organic solvent and the second organic solvent are stirred under the protection of an inert atmosphere. A stirring time is 1 min-10 min, and the QDs/S²⁻ is completely transferred to the phase of the second organic solvent by stirring. A separation and purification method of the first quantum dot includes: washing the mixed solution including the first quantum dot in the Step S02 with N-hexane, a washing times may be two or more times, and precipitating with acetonitrile to obtain a precipitate. The precipitate is the purified first quantum dots.

Step S03, forming second quantum dots QDs/M²⁻ connected with cationic groups by cationic ligand exchanging, and the specific steps include:
Providing a cationic ligand solution including cationic groups, and the cationic ligand solution includes a third organic solvent and cationic ligands dispersed in the third organic solvent;
Mixing the first quantum dot solution with the cationic ligand solution, and exchanging the anionic groups with the cationic groups to obtain second quantum dots, and the surface of each of the second quantum dots is connected with the cationic groups;
Dispersing the second quantum dots in the second organic solvent to obtain a second quantum dot solution.

The cationic ligands employed in the Step S03 includes a soluble metal salt, and a suitable soluble metal include one of Cd, Zn, Pb, Hg, and In. The third organic solvent includes an NMF (N-methylformamide) solvent, a DMSO (dimethyl sulfoxide) solvent, a MEK (methyl ethyl ketone) solvent or an ACN (acetonitrile) solvent.

The process diagram of the cation exchanging referring to FIG. 4. In order to promote the entry of the second quantum dots QDs/M²⁺ into the second organic solvent, the second quantum dots are precipitated with ethyl acetate, and then the precipitate is dispersed into the second organic solvent.

Step S04, fusing and assembling the first quantum dots and the second quantum dots to obtain quantum dot fusion units, the specific steps include:
Mixing the first quantum dot solution with the second quantum dot solution, the first quantum dots and the second quantum dots being fused and assembled to quantum dot fusion units.

Moreover, the step of mixing the first quantum dot solution with the second quantum dot solution includes: adding the first quantum dot solution into a flask, stirring for a period of time, wherein a stirring mode is ultrasonic for 10 s-60 s, adding the second quantum dot solution under the condition of vigorous stirring to obtain a mixed solution, continuously stirring the mixed solution for 1 h-24 h, and the first quantum dots QDs/S²⁻ and the second quantum dots QDs/M²⁺ are fused and assembled to form QDs-QDs quantum dot fusion units.

Step S05, separating the quantum dot fusion unit, and then dispersing the quantum dot fusion unit in a fourth organic solvent. A method of separating the quantum dot fusion unit includes: preparing an N-hexane reagent, adding oleylamine and oleic acid into the N-hexane reagent to produce phase layer separation, transferring the mixed solution containing QDs-QDs to the upper organic phase, adding ethanol to form a precipitate after complete phase transfer, the precipitate is a purified QDs-QDs, and dispersing the QDs-QDs in the octane reagent for use.

It should be noted that, in the quantum dot fusion unit prepared by the above-described production method, the core-shell structure of the first quantum dot and the core-shell structure of the second quantum dot are basically the same.

It should be noted that, in the preparation process of the second quantum dots, the first quantum dots are obtained by anionic ligand exchanging to the third quantum dots, and then performing cation ligand exchanging to the first quantum dots to obtain the second quantum dots. The surface of the first quantum dot is rich in cations, but organic ligands is connected to the surface of it, thereby it is necessary to replace the organic ligands with the anionic groups and then perform further manipulation. That is, it is generally difficult to directly connect cations to the surface of quantum dot, so it is necessary to connect anionic ligands first and then perform cation exchange to obtain the second quantum dot.

Taking Na₂S or (NH₄)₂S(NH₄)₂S as the anionic ligands as an example, a concentration of the anionic ligands in the anionic ligand solution is 1 mmol/mL-10 mmol/mL. It might be understood that, the concentration of the anionic ligands in the anionic ligand solution may be 2 mmol/mL, 3 mmol/mL, 4 mmol/mL, 5 mmol/mL, 6 mmol/mL, 7 mmol/mL, 8 mmol/mL, 9 mmol/mL, and a concentration or range between any of the above two concentrations.

Taking zinc acetate as the cationic ligands as an example, a concentration of the cationic ligands in the cationic ligand solution is 0.1 mmol/mL-10 mmol/mL. It might be understood that, the concentrations of the cationic ligand in the cationic ligand solution is 0.2 mmol/mL, 0.5 mmol/mL, 0.8 mmol/mL, 1 mmol/mL, 2 mmol/mL, 3 mmol/mL, 4 mmol/mL, 5 mmol/mL, and a concentration or range between any two of the above concentrations.

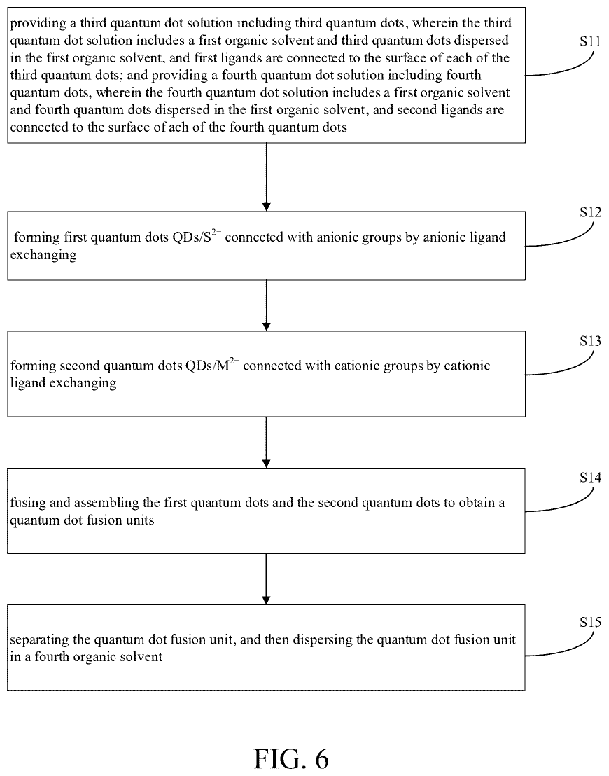

Fourth aspect, referring to FIG. 6, an embodiment of the present disclosure further provides a method of preparing quantum dot fusion units having different core-shell structures, wherein a core-shell structure of a first quantum dot is different from a core-shell structure of a second quantum dot, and the method includes:

Step S11, providing a third quantum dot solution including third quantum dots, the third quantum dot solution includes a first organic solvent and third quantum dots dispersed in the first organic solvent, and first ligands are connected to the surface of each of the third quantum dots;
Providing a fourth quantum dot solution including fourth quantum dots, wherein the fourth quantum dot solution includes a first organic solvent and fourth quantum dots dispersed in the first organic solvent, and second ligands are connected to the surface of each of the fourth quantum dots;
Providing an anionic ligand solution including anionic groups, the anionic ligand solution including a second organic solvent and anionic ligands dispersed in the second organic solvent.

Step S12: forming first quantum dots QDs/S²⁻ connected with anionic groups by anionic ligand exchanging, and the specific steps include:
Mixing the third quantum dot solution with the anionic ligand solution, and exchanging the first ligands with the anionic groups to obtain first quantum dots, and the surface of each of the first quantum dots is connected with the anionic groups; and dispersing the first quantum dots in the second organic solvent to obtain a first quantum dot solution.

The Step S12 further includes: forming third quantum dots connected with anionic groups by anionic ligand exchanging, and the specific steps include:
Mixing the fourth quantum dot solution with the anionic ligand solution, and exchanging the second ligands with the anionic groups to obtain fifth quantum dots, and the surface of each of the fifth quantum dots is connected with the anionic groups; and dispersing the fifth quantum dots in the second organic solvent to obtain a fifth quantum dot solution.

Step S13, forming second quantum dots QDs/M²⁻ connected with cationic groups by cationic ligand exchanging, and the specific steps include:
Providing a cationic ligand solution including cationic groups, and the cationic ligand solution includes a third organic solvent and cationic ligands dispersed in the third organic solvent;
Mixing the fifth quantum dot solution with the cationic ligand solution, and exchanging the anionic groups with the cationic groups to obtain second quantum dots, and the surface of each of the second quantum dots is connected with the cationic groups; and dispersing the second quantum dots in the second organic solvent to obtain a second quantum dot solution.

Step S14, fusing and assembling the first quantum dots and the second quantum dots to obtain quantum dot fusion units, the specific steps include:
Mixing the first quantum dot solution with the second quantum dot solution, the first quantum dots and the second quantum dots being fused and assembled into a quantum dot fusion unit.

Step S15, separating the quantum dot fusion unit, and then dispersing the quantum dot fusion unit in a fourth organic solvent. A method of separating the quantum dot fusion unit includes: preparing an N-hexane reagent, adding oleylamine and oleic acid into the N-hexane reagent to produce phase layer separation, transferring the mixed solution containing QDs-QDs to the upper organic phase, adding ethanol to form a precipitate after complete phase transfer, the precipitate is a purified QDs-QDs, and dispersing the QDs-QDs in the octane reagent for use.

Hereinafter, the present disclosure will be specifically described with reference to specific examples and comparative examples, and the following examples are only partial examples of the present disclosure and do not limit the present disclosure. The raw materials used in the following examples are, unless otherwise specified, commercially available products.

### Example 1

Example 1 provides a quantum dot light-emitting device including an anode, a hole injection layer, a hole transport layer, a light-emitting layer, an electron transport layer, and a cathode. The material of the anode is ITO, the material of the hole injection layer is PEDOT:PSS (Poly(3,4-ethylenedioxythiophene)-poly(styrene sulfonate)), the material of the hole transport layer is TFB (Poly(9,9-dioctylfluorene-co-N-(4-butylphenyl)diphenylamine)), the material of the electron transport layer is ZnO, and the material of the cathode is Ag.

The material of the light-emitting layer of the quantum dot light-emitting device of Example 1 is a green composite material, that is a green quantum dot. The band gap of the quantum dot is 2.28 eV. The method of preparing the composite material included:

Step S01: third quantum dots and fourth quantum dots having different core-shell structures were provided, wherein the third quantum dots has a non-electron-confined structure, material of the third quantum dot was configured as InZnP/ZnSeS, organic ligands connected to the surface of the third quantum dot are oleic acid and oleyamine; the fourth quantum dot includes a type I electron-confined and hole-confined structure, material of the fourth quantum dot is configured as InP/ZnS, and organic ligands connected to the surface of the fourth quantum dot are oleic acid and oleyamine;
Moreover, by adjusting the proportion of the alloy components on each layer of the first quantum dot, the valence band energy level difference between the core and the shell ΔE_{VB, shell-core}=−0.5 eV, the conductive energy level difference between the core and the shell ΔE_{CB, shell-core}=0.15 eV, and the electrons might be delocalized on the conduction band on the core and shell of the first quantum dot; and by adjusting the proportion of the alloy components on each layer of the second quantum dot, the valence band energy level difference between the core and the shell ΔE_{VB, shell-core}=−1.2 eV, the conductive energy level difference between the core and the shell ΔE_{CB, shell-core}=1 eV;
200 mg of InP/ZnS was dispersed in 5 mL of N-hexane solvent to obtain a third quantum dot solution;
200 mg of InZnP/ZnSeS was dispersed in 5 mL of N-hexane solvent to obtain a fourth quantum dot solution.

Step S02: anionic ligand exchanging, which specifically included:
5 mL of N-hexane solution including 200 mg of InP/ZnS was mixed with 10 mL of NMF solution including 50 mmol (NH₄)₂S, the immiscible two-phase solvent was stirred for 8 minutes under an inert atmosphere, it might be observed that the organic ligand on the surface of the third quantum dot was exfoliated, and S²⁻ was connected to the surface of the third quantum dot to form InP/ZnS/S²⁻, where InP/ZnS/S²⁻ was transferred to the NMF phase, the NMF phase where InP/ZnS/S²⁻ was included was washed twice with N-hexane reagent, ethyl formate was added to obtain a precipitate of InP/ZnS/S²⁻, and then he InP/ZnS/S²⁻ precipitate was separated and dispersed into 4 mL of NMF solvent;
5 mL of N-hexane solution including 200 mg of InZnP/ZnSeS was mixed with 10 mL of NMF (N-methylformamide) solution including 50 mmol (NH₄)₂S, the immiscible two-phase solvent was stirred under an inert atmosphere for 8 minutes, it might be observed that the organic ligand on the surface of the fourth quantum dot was exfoliated, and S²⁻ was connected to the surface of the fourth quantum dot to form InZnP/ZnSeS/S²⁻, where InZnP/ZnSeS/S²⁻ was transferred to the NMF phase, the NMF phase where InZnP/ZnSeS/S²⁻ was included was washed twice with N-hexane reagent, ethyl formate was added to obtain a precipitate of InZnP/ZnSeS/S²⁻, and then he InZnP/ZnSeS/S²⁻ precipitate was separated and dispersed into 4 mL of NMF solvent.

Step S03, InZnP/ZnSeS/S²⁻ was subjected to cation ligand exchange to obtain InZnP/ZnSeS/Zn²⁺, specifically included:

100 mg of zinc acetate was dissolved in 2 mL of NMF (N-methylformamide) solvent to form a cationic ligand solution, the cationic ligand solution was added to the NMF solution dispersed with InZnP/ZnSeS/S²⁻ of Step S02, the solution was stirred for 2 hours to obtain second quantum dot InZnP/ZnSeS/Zn²⁺, ethyl acetate was added to form a precipitate of InZnP/ZnSeS/Zn²⁺, and the precipitate was dispersed in 5 mL of NMF solvent for later use.

Step S04: NMF solution including InZnP/ZnSeS/Zn²⁺ was added into a flask and ultrasonicated for 30 seconds, NMF solution including InP/ZnS/S²⁻ was added under the condition of vigorous stirring, and the mixture was stirred for 10 hours to obtain a quantum dot fusion unit of InZnP/ZnSeS/Zn²⁺ and InP/ZnS/S²⁻.

Step S05: the quantum dot fusion unit of InZnP/ZnSeS/Zn²⁺ and InP/ZnS/S²⁻ was purified and stored, specifically including: 10 mL of N-hexane mixed solution was added to the mixed solution, where the N-hexane mixed solution includes 2 mL oleylamine and 2 mL oleic acid, stirred for 30 min to have the quantum dot fusion unit of InZnP/ZnSeS/Zn²⁺ and InP/ZnS/S²⁻ transferred into the organic phase of N-hexane, ethanol was added into the organic phase after the phase transfer was completed, and the precipitate was dispersed into octane reagent for later use.

A method of preparing the quantum dot light-emitting device of Example 1 included: a material of hole injection layer PEDOT:PSS was spin-coated on an anode layer ITO, and thermal annealed on a hot plate at 100° C. for 15 minutes; then, a hole transport layer with a material of TFB and a thickness of 30 nm was formed on the hole injection layer, and thermal annealed on a 100° C. hot plate for 15 minutes; a light-emitting layer of green quantum dot of InZnP/ZnSe/Zn²⁺ and InP/ZnS/S²⁻ was formed on the hole transport layer; an ethanol solution dispersed with ZnO was coated on the light-emitting layer, and thermal annealed on a hot plate at 80° C. for 10 minutes to form an electron transport layer; an Ag cathode electrode layer was formed by evaporation; and finally encapsulated to form an electroluminescent device.

The photoelectric performance and lifetime of the quantum dot light-emitting device prepared in Example 1 were tested, and the test results are shown in Table 1 below.

### Example 2

Example 2 provides a quantum dot light-emitting device in which the materials of the anode, the hole injection layer, the hole transport layer, and the cathode are the same as those of the corresponding functional layers of Example 1, except that the material of the electron transport layer of Example 2 is ZnMgO, and the light-emitting layer is a red quantum dot fusion unit.

The material of the light-emitting layer of the quantum dot light-emitting device of Example 2 is a red composite material, that is a red quantum dot. The band gap of the quantum dot is 1.97 eV. The method of preparing the composite material included:
Step S11: a third quantum dot was provided, wherein the third quantum dot has a non-hole confined structure, material of the third quantum dot are configured as CdZnSeS/ZnSe/ZnSeS, and the organic ligand connected to the surface of the quantum dot are oleic acid;
Moreover, by adjusting the proportion of the alloy components on each layer of the third quantum dot, the valence band energy level difference between the core and the shell ΔE_{VB, shell-core}=−0.1 eV, the conductive energy level difference between the core and the shell ΔE_{CB, shell-core}=0.55 eV, and the holes might be delocalized on the conduction band on the core and shell of the third quantum dot;
Step S12: CdZnSeS/ZnSe/ZnSeS/S²⁻ was formed by anionic ligand exchange, and the operation of the specific anionic ligand exchange process is the same as that in Example 1;
Step S13: CdZnSeS/ZnSe/ZnSeS/S²⁻ was exchanged by cationic ligand to obtain CdZnSeS/ZnSe/ZnSeS/Zn²⁺, and the specific operation of the cationic ligand exchange process is the same as that of Example 1;
Step S14: CdZnSeS/ZnSe/ZnSeS/Zn²⁺ and CdZnSeS/ZnSe/ZnSeS/S²⁻ were fused and assembled to obtain a quantum dot fusion unit of CdZnSeS/ZnSe/ZnSeS/Zn²⁺ and CdZnSeS/ZnSe/ZnSeS/S²⁻, and the specific fused and assembled operation is the same as that of Example 1;
Step S15: the quantum dot fusion unit of CdZnSeS/ZnSe/ZnSeS/Zn²⁺ and CdZnSeS/ZnSe/ZnSeS/S²⁻ was purified and stored, and the specific purified method and stored method are the same as those of Example 1.

The method of preparing the quantum dot light-emitting device of Example 2 is the same as that of Example 1, except that the above-described red quantum dot fusion unit was used to form the light-emitting layer and ZnMgO was used to form the electron transport layer.

The photoelectric performance and lifetime of the quantum dot light-emitting device prepared in Example 2 were tested, and the test results are shown in Table 1 below.

### Comparative Example 1

The quantum dot light-emitting devices provided in Comparative Example 1 are basically the same as those of Example 1, except that the materials of the light-emitting layers are a green quantum dot of InZnP/ZnSeS having a non-electron-confined structure and a green quantum dot of InP/ZnS having a type I electron-confined and hole-confined structure, respectively.

The photoelectric performance and lifetime of the quantum dot light-emitting devices prepared in Comparative Example 1 were tested, and the test results are shown in Table 1 below.

### Comparative Example 2

The quantum dot light-emitting device of Comparative Example 2 is basically the same as that of Example 2, except that the light-emitting layer is a red quantum dot of CdZnSeS/ZnSe/ZnSeS having a non-hole-confined structure.

The photoelectric performance and lifetime of the quantum dot light-emitting device prepared in Comparative Example 2 were tested, and the test results are shown in Table 1 below.

Description of testing equipment for photoelectric performance and lifetime testing of quantum dot light-emitting devices: the lifetime testing of quantum dot light-emitting device adopts a 128-channel lifetime testing system customized by Guangzhou New Vision Company. The system architecture is a constant voltage and constant current source to drive QLED to test changes in voltage or current; the photodiode detector and the test system test the changes in brightness (photocurrent) of the QLED; and the brightness meter tests the brightness (photocurrent) of the calibration QLED.

The PL parameter of light-emitting quantum dot light-emitting device excited by light is used to describe the wavelength (nm) corresponding to the maximum intensity of light emitted by quantum dot, the FWHM parameter of light-emitting quantum dot light-emitting device excited by light is used to describe the width (nm) of the valley of the luminescence peak, and the PLQY parameter of light-emitting quantum dot light-emitting device excited by light is used to evaluate the luminous efficiency of quantum dot.

The EL parameter of light-emitting quantum dot light-emitting device excited by electric field is used to describe the wavelength (nm) corresponding to the maximum intensity of electroluminescence. The FWHM parameter of light-emitting quantum dot light-emitting device excited by electric field is used to describe the width (nm) of the valley of the luminescence peak. The EQE of light-emitting quantum dot light-emitting device excited by electric field parameter is used to evaluate the efficiency of electron injection into the composite material and conversion into photons of the light-emitting device. T95 in the T95@1000 nits parameters of light-emitting quantum dot light-emitting device excited by electric field represents the time taken for the luminescent intensity of the luminescent device to decrease to 95% of the maximum value, which might be measured in hours or minutes, where 1000 nits means that the luminous intensity of the light-emitting device is 1000 nits. T95@1000 nits is generally used to test and evaluate the stability and durability of the light-emitting device, especially the long-term use performance under high brightness conditions.

By testing, the above parameters are shown in Table 1 and Table 2 below, respectively.

TABLE 1
Test results of luminescence performance and lifetime
performance of the light-emitting devices:

| | | PL | FWHM | PLQY |
|---|---|---|---|---|
| Test items | Light-emitting layer | (nm) | (nm) | (%) |
| Example 1 | QDs-QDs | 544 | 36 | 85 |
| Example 2 | QDs-QDs | 629 | 21 | 88 |
| Comparative | InZnP/ZnSeS | 544 | 36 | 80 |
| Example 1 | InP/ZnS | 544 | 37 | 75 |
| Comparative | CdZnSeS/ZnSe/ZnSeS | 629 | 21 | 80 |
| Example 2 | | | | |

TABLE 2
Test results of light luminescence performance and lifetime
performance of the quantum dot light-emitting devices:

| | | | | | T95@ |
|---|---|---|---|---|---|
| | | EL | FWHM | EQE | 1000 nit |
| Test items | Light-emitting layer | (nm) | (nm) | (%) | (h) |
| Example 1 | QDs-QDs | 545 | 38 | 20 | 150 |
| Example 2 | QDs-QDs | 630 | 22 | 19 | 4500 |
| Comparative | InZnP/ZnSeS | 547 | 38 | 14 | 60 |
| Example 1 | InP/ZnS | 546 | 39 | 13 | 55 |
| Comparative | CdZnSeS/ZnSe/ZnSeS | 631 | 22 | 15 | 2300 |
| Example 2 | | | | | |

It can be seen from the test data in Table 1 that, the PLQY parameter of Example 1 is significantly improved compared to Comparative Example 1, correspondingly, the fluorescence quantum yield and stability of the quantum dot light-emitting device provided in Example 1 are significantly improved; and the PLQY parameter of Example 2 is significantly improved compared to Comparative Example 2, correspondingly, the fluorescence quantum yield and stability of the quantum dot light-emitting device provided in Example 2 are significantly improved. That is, through the fusion assembly process of the first quantum dot with negative charge and the second quantum dot, the defect state on the surface of the quantum dot might be repaired, which is beneficial to improving the fluorescence quantum yield and stability.

It can be seen from the test data in Table 2 that, the EQE parameter of Example 1 is significantly improved compared to Comparative Example 1, correspondingly, the photon conversion rate of the quantum dot light-emitting device provided in Example 1 is significantly improved; and the EQE parameter of Example 2 is significantly improved compared to Comparative Example 2, correspondingly, the photon conversion rate of the quantum dot light-emitting device provided in Example 2 is significantly improved.

It can be seen from the test data in Table 2 that, the T95@1000 nits parameter of Example 1 is significantly improved compared to Comparative Example 1, correspondingly, the lifetime performance of the quantum dot light-emitting device provided in Example 1 is significantly improved; and the T95@1000 nits parameter of Example 2 is significantly improved compared to Comparative Example 2, correspondingly, the lifetime performance of the quantum dot light-emitting device provided in Example 2 is significantly improved.

Regarding the test data in Table 2, it should be noted that the green quantum dot light-emitting devices without cadmium system provided in Example 1 and Comparative Example 1 have a poor lifetime performance due to their material energy level characteristics, which is a normal phenomenon, while the quantum dot light-emitting devices including cadmium system provided in Example 2 and Comparative Example 2 have a high lifetime level due to their relatively mature preparation process level, which is a normal phenomenon.

The composite material and preparation method thereof, and the quantum dot light-emitting diode according to embodiments of the present disclosure are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of disclosure in accordance with the teachings of the present disclosure. In view of the foregoing, the content of the present specification should not be construed as limiting the disclosure.

What is claimed is:

1. A composite material, comprising:
a first quantum dot and a second quantum dot;
wherein, the surface of the first quantum dot is connected with an anionic group, and the surface of the second quantum dot is connected with a cationic group.

2. The composite material according to claim 1, wherein an element forming the anion group comprises one of S, Se, Te, and P; and an element forming the cationic group comprises one of Cd, Zn, Pb, Hg, and In.

3. The composite material according to claim 2, wherein a material of the second quantum dot comprises at least one metal element, and the element forming the cationic group is selected from the metal element in the material of the second quantum dot.

4. The composite material according to claim 1, wherein a number of charges of the anionic group is the same as a number of charges of the cationic group.

5. The composite material according to claim 1, wherein a ratio of a number of charges of the anionic group to a number of charges of the cationic group is (0.8-0.2):1.

6. The composite material according to claim 1, wherein both the first quantum dot and the second quantum dot are core-shell quantum dot, the anionic group is connected to the outer surface of the shell of the first quantum dot, and the cationic group is connected to the outer surface of the shell of the second quantum dot.

7. The composite material according to claim 1, wherein the composite material comprises a first type quantum dot having a first core-shell structure, a second type quantum dot having a second core-shell structure, and a third type quantum dot having a third core-shell structure;
wherein, the first core-shell structure is configured as a non-hole confined structure, the second core-shell structure is configured as a non-electron confined structure, and the third core-shell structure is configured as a type I electron-confined and hole-confined core-shell structure.

8. The composite material according to claim 7, wherein both the first quantum dot and the second quantum dot are configured as the first type quantum dot having the first core-shell structure, thereby the composite material is configured to facilitate hole injection.

9. The composite material according to claim 7, wherein one of the first quantum dot and the second quantum dot is configured as the first type quantum dot having the first core-shell structure, and another of the first quantum dot and the second quantum dot is configured as the third type quantum dot having the third core-shell structure, thereby the composite material is configured to facilitate hole injection.

10. The composite material according to claim 7, wherein both the first quantum dot and the second quantum dot are configured as the second type quantum dot having the second core-shell structure, thereby the composite material is configured to facilitate electron injection.

11. The composite material according to claim 7, wherein one of the first quantum dot and the second quantum dot is configured as the second type quantum dot having the second core-shell structure, and another of the first quantum dot and the second quantum dot is configured as the third type quantum dot having the third core-shell structure, thereby the composite material is configured to facilitate electron injection.

12. The composite material according to claim 7, wherein both the first quantum dot and the second quantum dot are configured as the third type quantum dot having the third core-shell structure, thereby the composite material is configured to facilitate balanced transport of hole and electron.

13. The composite material according to claim 7, wherein one of the first quantum dot and the second quantum dot comprises the first type quantum dot having the first core-shell structure, and another of the first quantum dot and the second quantum dot is configured as the second type quantum dot having the second core-shell structure, thereby the quantum dot is configured to facilitate balanced transport of hole and electron.

14. The composite material according to claim 7, wherein the first quantum dot comprises the first type quantum dot having the first core-shell structure, the second type quantum dot having the second core-shell structure, and the third type quantum dot having the third core-shell structure; the second quantum dot comprises the first type quantum dot having the first core-shell structure, the second type quantum dot having the second core-shell structure, and the third type quantum dot having the third core-shell structure; thereby the composite material is configured to facilitate balanced transport of hole and electron.

15. The composite material according to claim 1, wherein an average particle diameter of the first quantum dot is 5 nm-25 nm;
an average particle diameter of the second quantum dot is 5 nm-25 nm;
the first quantum dot and the second quantum dot each independently comprises one or more of a single structure quantum dot, a core-shell quantum dot, and a perovskite-type semiconductor material; a material of the single structure quantum dot, a core material of the core-shell quantum dot, and a shell material of the core-shell quantum dot may comprise one or more of a Group II-VI compound, a Group IV-VI compound, a Group III-V compound, and a Group I-III-VI compound, respectively, the Group II-VI compound comprises one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the Group IV-VI compound comprises one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe; the Group III-V compound comprises one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the Group I-III-VI compound comprises one or more of CuInS₂, CuInSe₂, and AgInS₂; the perovskite-type semiconductor material comprises a doped or undoped inorganic perovskite-type semiconductor or an organic-inorganic hybrid perovskite-type semiconductor, the inorganic perovskite-type semiconductor has a structural general formula AMX₃, where A is a Cs⁺ ion; M is a divalent metal cation comprising one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺; X is a halogen anion comprising one or more of Cl⁻, Br⁻, and I⁻; the organic-inorganic hybrid perovskite-type semiconductor comprises CH₃(CH₂)ₙ₋₂NH₃⁺ or [NH₃(CH₂)ₙNH₃]²⁺, where n≥2; M is a divalent metal cation comprising one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺; and X is a halogen anion comprising one or more of Cl⁻, Br⁻, and I⁻.

16. A method of preparing a composite material, comprising:
providing a third quantum dot solution comprising third quantum dots, the third quantum dot solution comprises a first organic solvent and third quantum dots dispersed in the first organic solvent, and first ligands are connected to the surface of each of the third quantum dots;
providing an anionic ligand solution comprising anionic groups, and the anionic ligand solution comprises a second organic solvent and anionic ligands dispersed in the second organic solvent;
mixing the third quantum dot solution with the anionic ligand solution, and exchanging the first ligands with the anionic groups to obtain first quantum dot, and the surface of each of the first quantum dots is connected with the anionic groups;
separating the first quantum dots, and dispersing the first quantum dots in the second organic solvent to obtain a first quantum dot solution;
providing a cationic ligand solution comprising cationic groups, and the cationic ligand solution comprises a third organic solvent and cationic ligands dispersed in the third organic solvent;
mixing the first quantum dot solution with the cationic ligand solution, and exchanging the anionic groups with the cationic groups to obtain second quantum dots, and the surface of each of the second quantum dots is connected with the cationic groups;
dispersing the second quantum dots in the second organic solvent to obtain a second quantum dot solution;
mixing the first quantum dot solution with the second quantum dot solution to obtain the composite material.

17. The method according to claim 16, wherein the anionic ligands comprise Na₂S or (NH₄)₂S;
the cationic ligands comprise a soluble metal salt, and the soluble metal comprise one of Cd, Zn, Pb, Hg, and In;
the first organic solvent is an C6-C18 alkane;
the second organic solvent comprises NMF, DMSO, MEK, ACN, or a thiol organic solvent;
the second organic solvent comprises NMF, DMSO, MEK, or ACN;
the first ligands comprise decanoic acid, undecylenic acid, myristanoic acid, oleic acid, linoleic acid, stearic acid, octanethiol, dodecylmercaptan, octadecylmercaptan, oleylamine, octadecylamine, octylamine, dioctylamine, trioctylamine, tri-n-octylphosphine, tri-n-octylphosphine oxide.

18. A method of preparing a composite material, comprising:
providing a third quantum dot solution comprising third quantum dots, the third quantum dot solution comprises a first organic solvent and third quantum dots dispersed in the first organic solvent, and first ligands are connected to the surface of each of the third quantum dots;
providing a fourth quantum dot solution comprising fourth quantum dots, wherein the fourth quantum dot solution comprises a first organic solvent and fourth quantum dots dispersed in the first organic solvent, and second ligands are connected to the surface of each of the fourth quantum dots;
providing an anionic ligand solution comprising anionic groups, and the anionic ligand solution comprises a second organic solvent and anionic ligands dispersed in the second organic solvent;
mixing the third quantum dot solution with the anionic ligand solution, and exchanging the first ligands with the anionic groups to obtain first quantum dots, and the surface of each of the first quantum dots is connected with the anionic groups; and dispersing the first quantum dots in the second organic solvent to obtain a first quantum dot solution;
mixing the fourth quantum dot solution with the anionic ligand solution, and exchanging the second ligands with the anionic groups to obtain fifth quantum dots, and the surface of each of the fifth quantum dots is connected with the anionic groups; and dispersing the fifth quantum dots in the second organic solvent to obtain a fifth quantum dot solution;
providing a cationic ligand solution comprising cationic groups, and the cationic ligand solution comprises a third organic solvent and cationic ligands dispersed in the third organic solvent;
mixing the fifth quantum dot solution with the cationic ligand solution, and exchanging the anionic groups with the cationic groups to obtain second quantum dots, and the surface of each of the second quantum dots is connected with the cationic groups; and dispersing the second quantum dots in the second organic solvent to obtain a second quantum dot solution;
mixing the first quantum dot solution with the second quantum dot solution to obtain the composite material.

19. The method according to claim 18, wherein the anionic ligands comprise Na₂S or (NH₄)₂S;
the cationic ligands comprise a soluble metal salt, and the soluble metal comprise one of Cd, Zn, Pb, Hg, and In;
the first organic solvent is an C6-C18 alkane;
the second organic solvent comprises NMF, DMSO, MEK, ACN, or a thiol organic solvent;
the second organic solvent comprises NMF, DMSO, MEK, or ACN;
the first ligands comprise decanoic acid, undecylenic acid, myristanoic acid, oleic acid, linoleic acid, stearic acid, octanethiol, dodecylmercaptan, octadecylmercaptan, oleylamine, octadecylamine, octylamine, dioctylamine, trioctylamine, tri-n-octylphosphine, tri-n-octylphosphine oxide;
the second ligands comprise decanoic acid, undecylenic acid, myristanoic acid, oleic acid, linoleic acid, stearic acid, octanethiol, dodecylmercaptan, octadecylmercaptan, oleylamine, octadecylamine, octylamine, dioctylamine, trioctylamine, tri-n-octylphosphine, tri-n-octylphosphine oxide.

20. A quantum dot light-emitting device, comprising:
an anode;
a cathode; and
a light-emitting layer disposed between the anode and the cathode;
wherein a material forming the light-emitting layer comprises the composite material according to claim 1.
